(19) United States
(12) Patent Application Publication
(10) Pub. No.: US 2006/0220257 A1
(43) Pub. Date: Oct. 5, 2006

(54) Multi-chip package and method for manufacturing the same

(76) Inventor: Dae-Ho Lee, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/343,617

(22) Filed: Jan. 30, 2006

(30) Foreign Application Priority Data
Mar. 21, 2005 (KR) 2005-23112

(51) Int. Cl. H01L 23/52

(52) U.S. Cl. 257/777

(57) ABSTRACT

A multi-chip package includes a first chip group including at least one semiconductor chip on a substrate. The first chip group may be sealed to form a first package body. Connecting test terminals to ball pads allows package-level testing of the first chip group. A second chip group including at least one semiconductor chip may be provided on the first package body. The first package body and the second chip group may be sealed to form a second package body. The multi-chip package may further comprise an interposer substrate provided between the first package body and, for example, the lowest semiconductor chip of the second chip group. The interposer substrate may electrically connect the second chip group to the substrate.

### CROSS REFERENCE TO RELATED APPLICATIONS

This U.S. non-provisional application claims benefit of priority under 35 U.S.C. §119 of Korean Patent Application No. 2005-23112, filed on Mar. 21, 2005, the entire contents of which are incorporated herein by reference.

### BACKGROUND OF THE INVENTION

1. Field of the Invention

The present invention relates to a semiconductor packaging technique, and more particularly, to a multi-chip package and a method for manufacturing the same.

2. Description of the Related Art

Demands continue for semiconductor products that are lighter, smaller and thinner, and include multiple semiconductor chips. To meet such demands, multi-chip semiconductor packages have been developed.

Multi-chip semiconductor packages may include at least two semiconductor chips in a single semiconductor package. The semiconductor chips may be the same or different kinds of semiconductor chips. The semiconductor chips may be vertically or horizontally arranged on a substrate.

FIG. 1 is a cross-sectional view of a conventional multi-chip package 100.

Referring to FIG. 1, the multi-chip package 100 may comprise a substrate 10 and semiconductor chips 20, 30 and 40. The semiconductor chips 20, 30 and 40 may be vertically stacked on the top surface of the substrate 10. The semiconductor chips 20, 30 and 40 may be electrically connected to the substrate 10 using bonding wires 50. The substrate 10 and semiconductor chips 20, 30 and 40 may be simultaneously sealed to form a package body 60. Solder balls 70 may be formed on the bottom surface of the substrate 10.

If the upper semiconductor chip of adjacent semiconductor chips is equal or larger in size than the lower semiconductor chip of adjacent semiconductor chips, the bonding wires of the lower semiconductor chip may contact the upper semiconductor chip, causing a short circuit. To prevent the short circuit, a spacer may be interposed between the upper and lower semiconductor chips. The spacer may have such a thickness that the bonding wires of the lower semiconductor chip do not contact the upper semiconductor chip.

The conventional multi-chip package 100 may have negative impact on production rates. Once joined in a single package, the chip and package as a whole is tested, e.g., by package-level testing, by way of external package terminals. Faulty chips can dramatically impact production rates because a single faulty chip among the semiconductor chips 20, 30 and 40 will cause failure of the entire multi-chip package 100. Testing individual chips, e.g., chip-level testing, prior to packaging can avoid such impact. Therefore, the semiconductor chips 20, 30 and 40 are sometimes tested at chip level, e.g., prior to packaging, but such more sophisticated chip-level testing techniques may result in increased overall production costs.

In particular, if a multi-chip package includes memory chips and application specific integrated circuits (ASICs), for example logic chips, the multi-chip package may bear an excess burden of production costs, especially when the less expensive and more failure-prone memory chips cause failure of an entire multi-chip package containing otherwise viable logic chips. As will be appreciated, once packaged with the unusable memory chips the otherwise viable logic chips have little or no value, e.g., the entire package is discarded or at best possesses limited functionality.

Generally, the memory chips may be fabricated in large quantities and at a relatively low price. The logic chips may be fabricated according to the requirements of users and at a relatively high price. Generally, the memory chips may show higher fault rates than the logic chips.

In testing, semiconductor packages having memory chips may be tested under harsher conditions than those having logic chips. On the other hand, semiconductor packages having logic chips may be tested under milder conditions than those having memory chips.

The conventional multi-chip packages including memory chips and logic chips may be passed through a test process for either memory chips or logic chips. For example, if the multi-chip packages are tested using a testing process for logic chips, memory chips that would have been determined to be faulty under typical test conditions for memory chips, may be passed. This may cause faulty multi-chip packages.

If the multi-chip packages are tested using a testing process for memory chips, logic chips that would have been passed under typical test conditions for logic chips, may be determined to be faulty.

### SUMMARY

An example embodiment of the present invention provides a multi-chip package with improved overall production rates.

Another example embodiment of the present invention provides a multi-chip package enabling separate testing of logic chips, e.g., after, separate testing of memory chips. In the manufacture of a multi-chip semiconductor package, embodiments of the present invention offer improvement in allowing package-level testing of a first chip group prior to committing to incorporation, e.g., packaging, of a second chip group therewith. As a result, failure of relatively less expensive and more failure-prone chips, e.g., memory chips, does not waste viable and more expensive chips, e.g., logic chips. According to an example embodiment of the present invention, a multi-chip package may provide a first chip group including at least one semiconductor chip on a substrate. The first chip group may be sealed to form a test-ready first package body. For example, test terminals may be connected to ball pads to allow testing of the first chip group. For a first package body passing testing, a second chip group including at least one semiconductor chip may be provided on the first package body. The first package body and the second chip group may be sealed to form a second package body.

The first chip group may include two or more semiconductor chips, and the semiconductor chips may be vertically or horizontally arranged on the substrate.

The second chip group may include two or more semiconductor chips, and the semiconductor chips may be vertically or horizontally arranged on the first package body.

According to certain embodiments of the invention, an interposer substrate may be provided between the first package body and, for example, the lowest semiconductor chip of the second chip group. The interposer substrate may electrically connect the second chip group to the substrate. The interposer substrate may be selected from a group including, but not limited to, a lead frame, a printed circuit board, a tape wiring substrate, and a silicon substrate.

The semiconductor chips of the second chip group may be electrically connected to the interposer substrate using bonding wires and the interposer substrate may be electrically connected to the substrate using bonding wires. The lowest semiconductor chip of the second chip group, for example, may be flip chip bonded to the interposer substrate.

The interposer substrate may have patterns extending beyond the first package body and be electrically connected to the substrate.

The first chip group may include memory chips, and the second chip group may include logic chips.

A method for manufacturing a multi-chip package may comprise preparing a substrate having substrate pads. A first chip group may be mounted on one surface of the substrate. The first chip group may be sealed to form a first package body. Connecting test terminals to, for example, the ball pads of the substrate allow testing of the first chip group in its package form. A second chip group may be mounted on the first package body. The first package body and the second chip group may be sealed to form a second package body.

The method may further comprise providing an interposer substrate between the first package body and, for example, the lowest semiconductor chip of the second chip group to electrically connect the second chip group to the substrate.

### BRIEF DESCRIPTION OF THE DRAWINGS

The example embodiments of the present invention will be readily understood with reference to the following detailed description thereof as provided in conjunction with the accompanying drawings, wherein like reference numerals designate like structural elements.

FIG. 1 (Prior Art) is a cross-sectional view of a conventional multi-chip package.

FIG. 2 is a cross-sectional view of a multi-chip package in accordance with an example embodiment of the present invention.

FIGS. 3-7 are cross-sectional views showing steps of a method for manufacturing a multi-chip package in accordance with an example embodiment of the present invention.

FIG. 3 is a cross-sectional view showing a first chip and a second chip on a substrate.

FIG. 4 is a cross-sectional view showing a first package body.

FIG. 5 is a cross-sectional view showing testing the first and second chips.

FIG. 6 is a cross-sectional view showing mounting a third chip on the first package body.

FIG. 7 is a cross-sectional view showing a second package body.

FIG. 8 is a cross-sectional view of a multi-chip package in accordance with another example embodiment of the present invention.

FIG. 9 is a cross-sectional view of a multi-chip package in accordance with another example embodiment of the present invention.

FIG. 10 is a cross-sectional view of a multi-chip package in accordance with another example embodiment of the present invention.

FIG. 11 is a cross-sectional view of a multi-chip package in accordance with another example embodiment of the present invention.

FIG. 12 is a cross-sectional view of a multi-chip package in accordance with another example embodiment of the present invention.

FIG. 13 is a cross-sectional view of a multi-chip package in accordance with another example embodiment of the present invention.

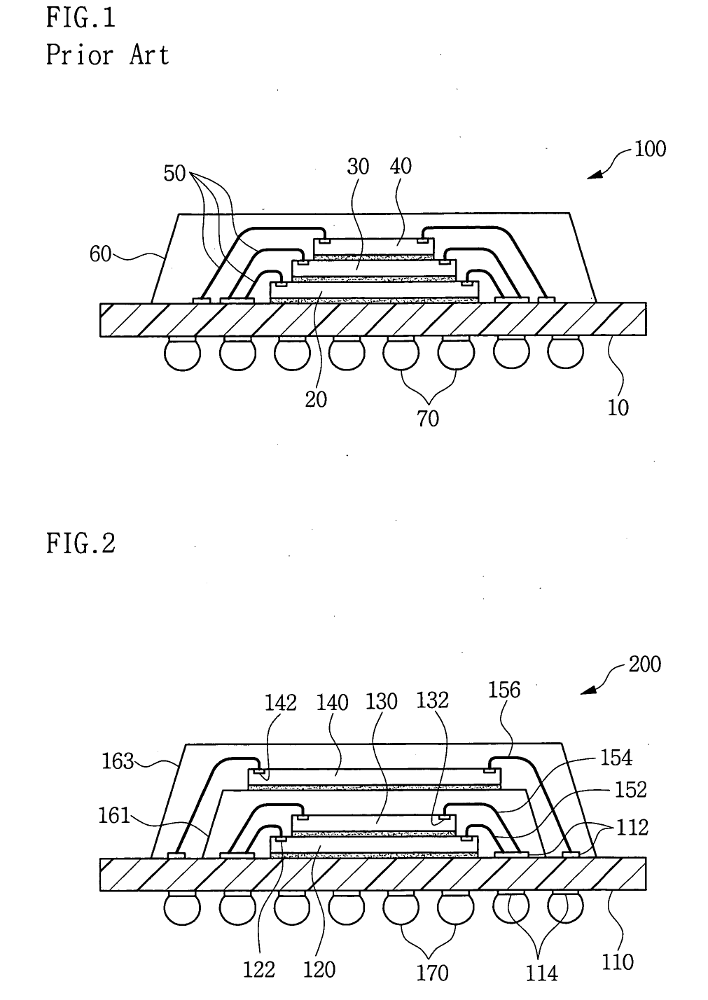

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the invention.

### DETAILED DESCRIPTION

Example, non-limiting embodiments of the present invention will now be described more fully with reference to the accompanying drawings. This invention may, however, be embodied in many different forms and should not be construed as limited to the particular example embodiments set forth herein. Rather, the disclosed embodiments are provided as illustrative disclosure, and will convey the invention to those skilled in the art. The principles and features of this invention, therefore, may be employed in varied and numerous embodiments without departing from the scope of the invention.

It should be noted that the figures are intended to illustrate the general characteristics of methods and devices of example embodiments of this invention and for the purpose of the description of such example embodiments herein. These drawings are not, however, to scale and may not precisely reflect the characteristics of any given embodiment, and should not be interpreted as defining or limiting the range of values or properties of example embodiments within the scope of this invention. Rather, for simplicity and clarity of illustration, the dimensions of some of the elements are exaggerated relative to other elements.

Further, well-known structures and processes are not described or illustrated in detail to avoid obscuring embodiments of the present invention. Like reference numerals are used for like and corresponding parts of the various drawings.

FIG. 2 is a cross-sectional view of a multi-chip package 200 in accordance with an example embodiment of the present invention.

The multi-chip package 200 may comprise a substrate 110 and a plurality of semiconductor chips 120, 130 and 140. The lowest semiconductor chip 120 may be hereinafter referred to as a first chip 120, the intermediate semiconductor chip 130 as a second chip 130 and the uppermost semiconductor chip 140 as a third chip 140. The first chip 120 may be mounted on the substrate 110 and the second chip 130 may be mounted on the first chip 120. A first package body 161 may be configured to seal the first and second chips 120 and 130. As described more fully hereafter, once so configured chips 120 and 130 may be tested by way of package-external connections, e.g., by package-level testing. Assuming chips 120 and 130 pass testing, the third chip 140 may be mounted on the first package body 161. A second package body 163 may be configured to seal the first package body 161 and the third chip 140.

Although this example embodiment shows two semiconductor chips vertically arranged in the first package body 161 and a single semiconductor chip provided on the first package body 161, at least one semiconductor chip might be vertically and/or horizontally formed in and/or on the first package body 161.

At least one semiconductor chip formed in the first package body 161 may be hereinafter referred to as a first chip group. At least one semiconductor chip formed on the first package body 161 may be hereinafter referred to as a second chip group.

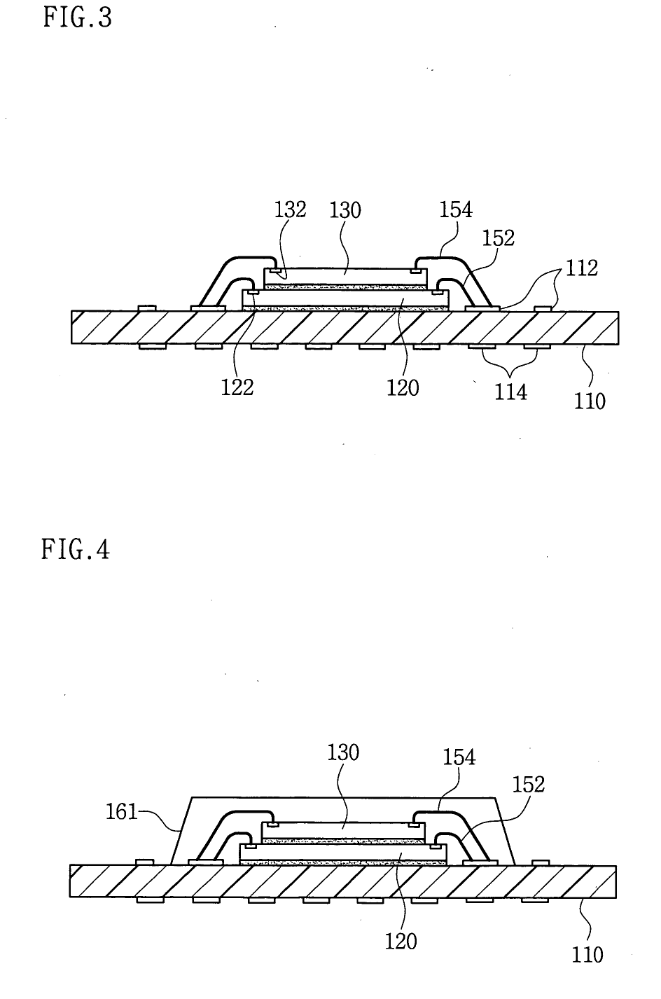

FIGS. 3 through 7 are cross-sectional views showing steps of a method for manufacturing a multi-chip package 200 in accordance with an example embodiment of the present invention.

Referring to FIG. 3, a substrate 110 may be provided. The substrate 110 may have substrate pads 112 formed on the top surface and ball pads 114 formed on the bottom surface. The ball pads 114 may be electrically connected to the substrate pads 112 using internal wirings (not shown). The substrate 110 may include, for example, a printed circuit board, a tape wiring substrate, a ceramic substrate, or a lead frame.

A first chip 120 may be mounted on the substrate 110 and a second chip 130 may be stacked on the first chip 120. The first chip 120 may have first chip pads 122 formed on the active surface thereof. First bonding wires 152 may electrically connect the substrate pads 112 to the first chip pads 122. The second chip 130 may have second chip pads 132 on the active surface thereof. Second bonding wires 154 may electrically connect the substrate pads 112 to the second chip pads 132. The second chip 130 may be located between the first chip pads 122, e.g., to leave exposed the first chip pads 122.

Although this example embodiment shows the second chip 130 smaller in size than the first chip 120, the second chip 130 may be equal or larger in size than the first chip 120. In this case, a spacer may be interposed between the first and second chips 120 and 130.

Referring to FIG. 4, a first package body 161 may be formed. For example, a liquid molding resin may seal the first and second chips 120 and 130 and the first and second bonding wires 152 and 154 to form the first package body 161. The liquid molding resin may include an epoxy as a molding compound.

The first and second chips 120 and 130 may be selected from semiconductor chips having a relatively poor reliability, as compared to that of a third chip 140. For example, if a multi-chip package includes memory chips and logic chips, the first and second chips 120 and 130 may be memory chips.

Generally, memory chips may be fabricated in large quantities and at a relatively low price. The logic chips may be fabricated in small quantities and at a relatively high price. Generally, the memory chips may show higher fault rates than the logic chips. Further, memory chips may be tested under harsher conditions than logic chips. In turn, logic chips may be tested under milder conditions than memory chips. Advantageously, the multi-chip package some embodiments of the present invention present an opportunity to test the relatively less reliable memory chips provided in the first package body 161 before committing the relatively more expensive logic chips, e.g., before mounting the logic chips. In this manner, the more valuable logic chips need not be committed to packaging with memory chips having faults. In other words, viable and more reliable logic chips are not lost to less expensive faulty memory chips.

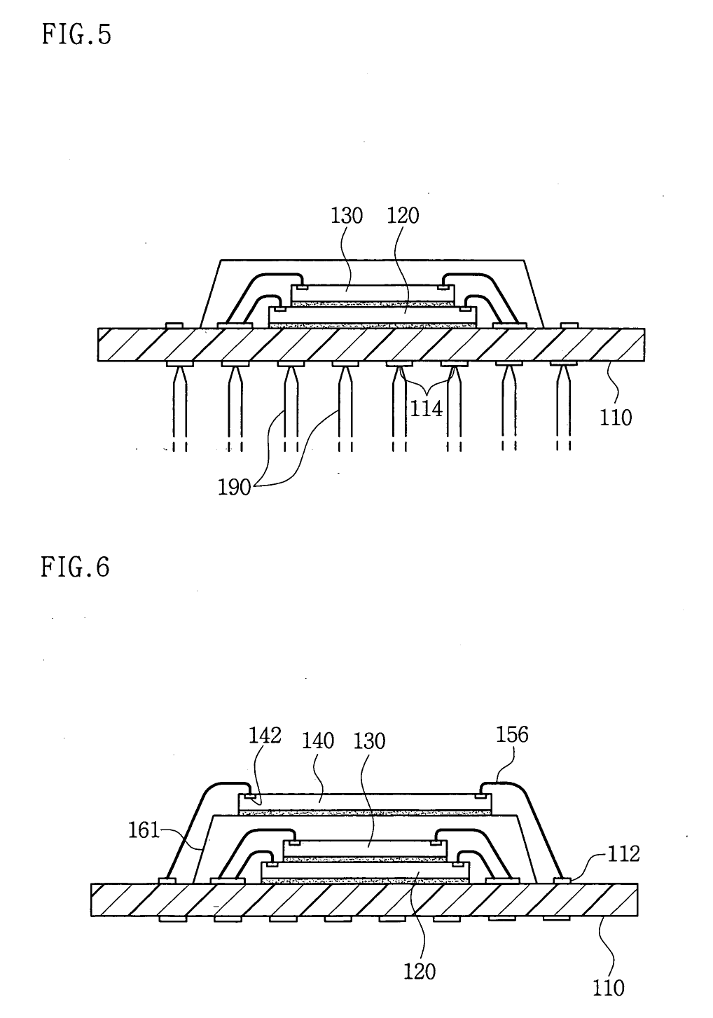

Referring to FIG. 5, a test process may be performed on the first and second chips 120 and 130. The ball pads 114 of the substrate 110 may be connected to test terminals 190 of a testing device to test the first and second chips 120 and 130. As will be appreciated, such package-level testing is more easily accomplished than chip-level testing.

The resultant molded part may comprise the substrate 110 having the ball pads 114, the first and second chips 120 and 130 mounted on the substrate 110, and the first package body 161. Since the structure of the molded part may be substantially equivalent to that of a land grid array (LGA) package, the molded part may be tested using a testing device for a LGA package.

For example, if the first and second chips 120 and 130 are memory chips, the molded part may be tested under test conditions appropriate for a semiconductor package having memory chips. After a test process, the molded part including any memory chip that has been determined to be faulty may be removed from production. Therefore, the molded part having memory chips that passed a test process may be used in subsequent processes, e.g., as in adding additional chips to the package.

Referring to FIG. 6, the third chip 140 may be mounted on the first package body 161.

The third chip 140 may have third chip pads 142 formed on the active surface thereof. Third bonding wires 156 may electrically connect the third chip pads 142 to the substrate pads 112.

The third chip 140 may be a semiconductor chip having relatively higher reliability than the first and second chips 120 and 130. For example, if the multi-chip package includes memory chips and logic chips, the third chip 140 may be a logic chip.

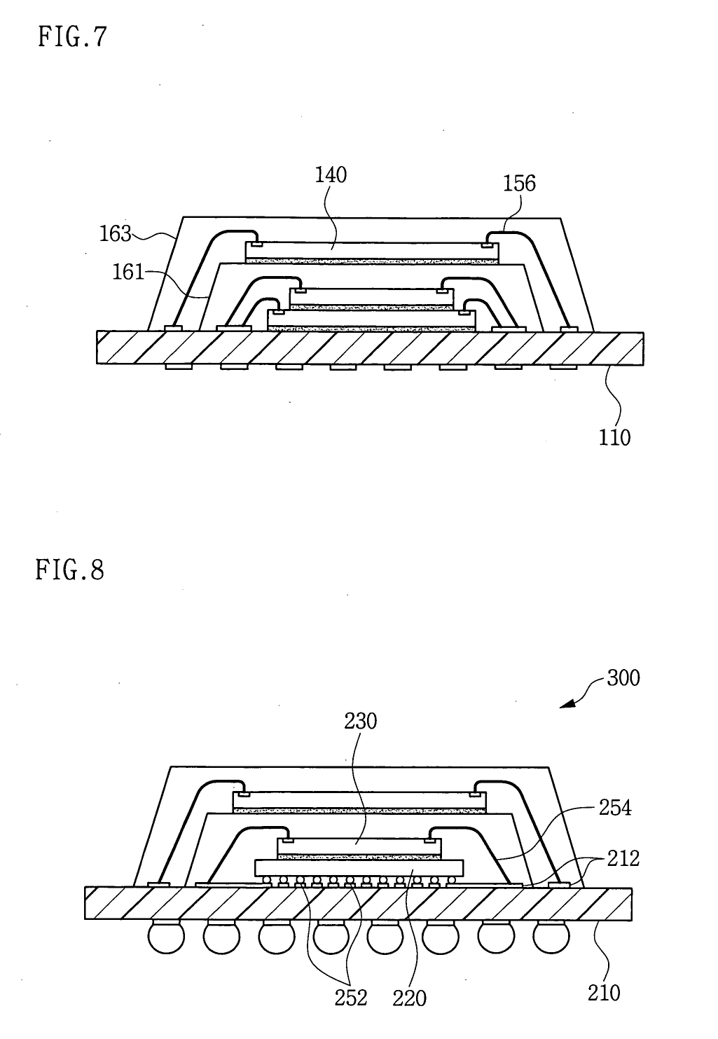

Referring to FIG. 7, a second package body 163 may be formed. A liquid molding resin may seal the first package body 161, the third chip 140 and the third bonding wires 156 to form the second package body 163.

Returning to FIG. 2, solder balls 170 may be formed on the bottom surface of the substrate 110. A flux may be applied to the ball pads 114. Solder balls may be attached to the ball pads 114 and be passed through a reflow process. The solder balls 170 may be replaced by Ni bumps or Au bumps.

A test process may be performed on the third chip 140. If the third chip 140 is a logic chip, the third chip 140 may be tested under test conditions appropriate for a logic chip.

Thus, the multi-chip package 200 in accordance with this example embodiment of the present invention may test the first, second and third chips 120, 130 and 140, respectively, in conformity with their characteristics.

Although this example embodiment shows an electrical connection of the substrate 110 and the first chip 120 using the bonding wires 152, the electrical connection need not be limited in this regard.

For example, a first chip may be electrically connected to a substrate using a flip chip bonding method.

FIG. 8 is a cross-sectional view of a multi-chip package 300 in accordance with another example embodiment of the present invention.

Referring to FIG. 8, the multi-chip package 300 may have a similar structure as the multi-chip package 200, except for having a first chip 220 flip chip bonded to a substrate 210. The first chip 220 may have bumps 252 connected to substrate pads 212 of the substrate 210. The detailed description of the same elements may be herein omitted.

Although the above described example embodiments show a single semiconductor chip provided on the first package body, the quantity of the semiconductor chips in the second group need not be limited in this regard.

For example, two semiconductor chips, or more, may be formed as the second group on a first package body.

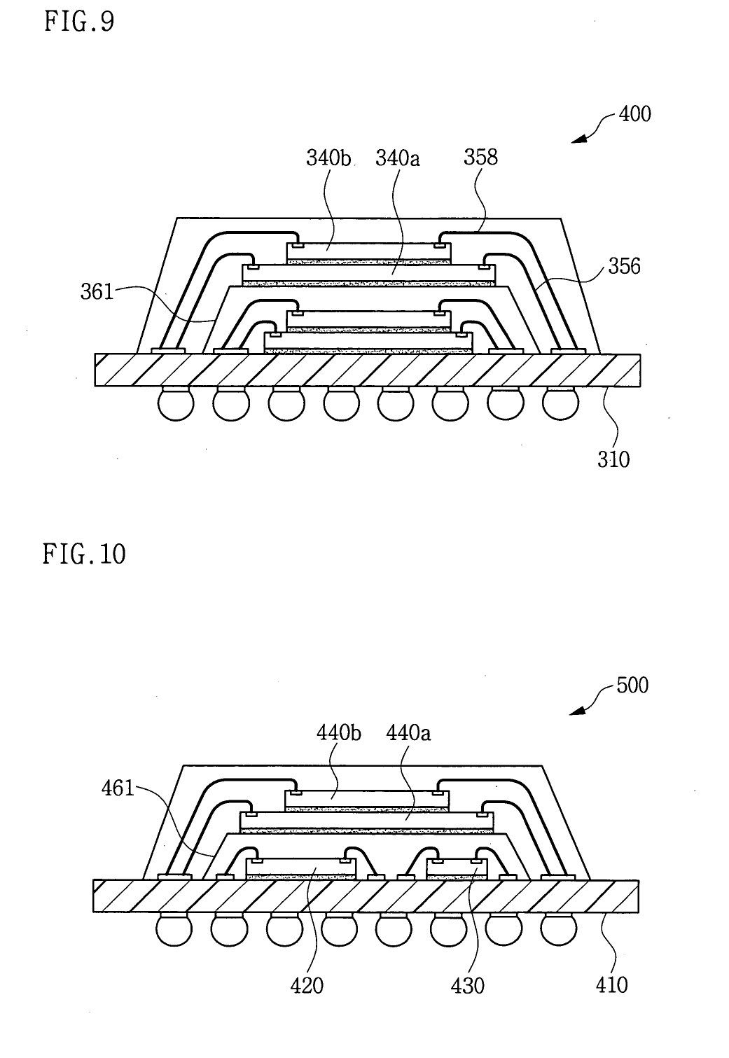

FIG. 9 is a cross-sectional view of a multi-chip package 400 in accordance with another example embodiment of the present invention.

Referring to FIG. 9, the multi-chip package 400 may include a third chip 340a and a fourth chip 340b provided on a first package body 361. The third chip 340a may be mounted on the first package body 361 and the fourth chip 340b may be vertically stacked on the third chip 340a. Third bonding wires 356 may electrically connect the third chip 340a to a substrate 310 and fourth bonding wires 358 may electrically connect the fourth chip 340b to the substrate 310.

Although this example embodiment shows semiconductor chips vertically stacked on the first package body, the semiconductor chips may be horizontally arranged on the first package body.

Further, although the above described example embodiments show semiconductor chips vertically stacked on the substrate, the semiconductor chips need not be limited in this regard.

For example, semiconductor chips may be horizontally arranged on a substrate.

FIG. 10 is a cross-sectional view of a multi-chip package 500 in accordance with another example embodiment of the present invention.

Referring to FIG. 10, the multi-chip package 500 may include a first chip 420 and a second chip 430 horizontally arranged on a substrate 410.

Although this example embodiment also shows the third and fourth chips vertically arranged on the first package body 461, the third and fourth chips need not be limited in this regard.

A multi-chip package in accordance with another example embodiment of the present invention may further comprise an interposer substrate.

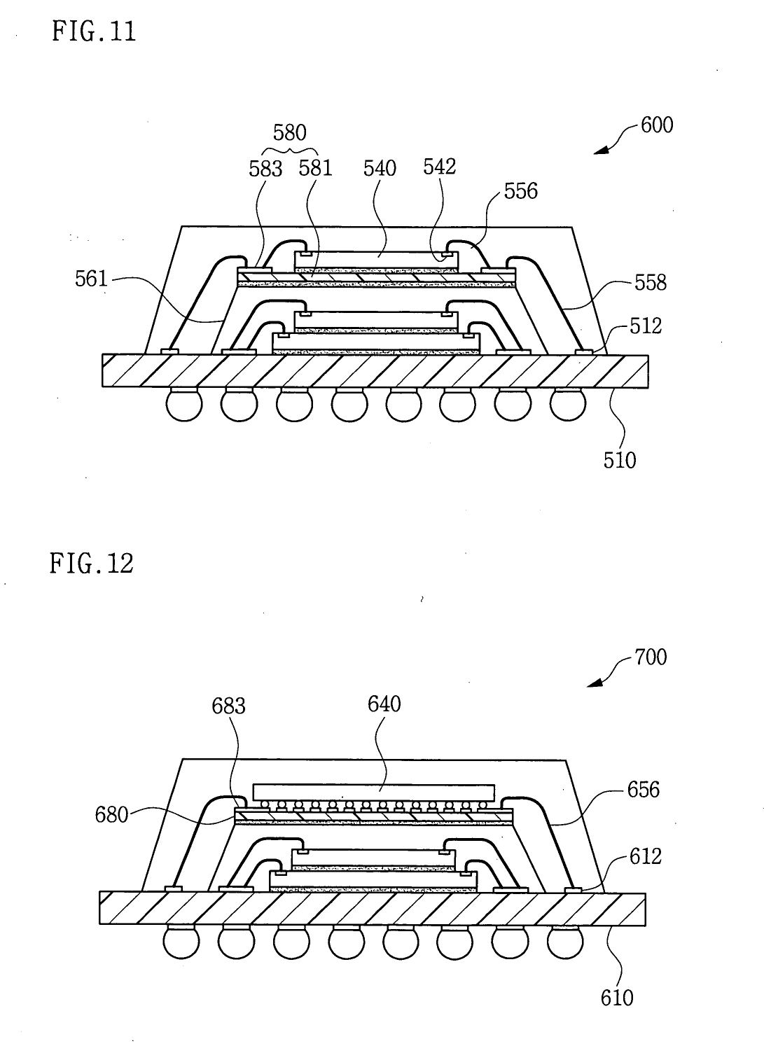

Referring to FIG. 11, a multi-chip package 600 may have a similar structure as the multi-chip package 200, except for having an interposer substrate 580. The interposer substrate 580 may be attached to the top surface of a first package body 561. The interposer substrate 580 may have patterns 583 formed on the top surface thereof. The interposer substrate 580 may include, for example, a lead frame, a tape wiring substrate, a printed circuit board and a silicon substrate.

A third chip 540 may be attached to the top surface of the interposer substrate 580. The third chip 540 may have third chip pads 542 formed on the active surface. Third bonding wires 556 may electrically connect the patterns 583 to the third chip pads 542.

Fourth bonding wires 558 may electrically connect substrate pads 512 of a substrate 510 to the patterns 583 of the interposer substrate 580. The third chip 540 may be smaller in size than the interposer substrate 580 so that the substrate 510 may be electrically connected to the interposer substrate 580 using the fourth bonding wires 558.

Although this example embodiment shows a single semiconductor chip provided on the interposer substrate 580, at least one semiconductor chip may be vertically or horizontally arranged on the interposer substrate 580.

Referring to FIG. 12, a multi-chip package 700 may comprise an interposer substrate 680 having patterns 683. A third chip 640 may be flip chip bonded to the patterns 683. Third bonding wires 612 may electrically connect substrate pads 612 of a substrate 610 to the patterns 683 of the interposer substrate 680.

The interposer substrate 680 may include, for example, a lead frame, a tape wiring substrate, a printed circuit board or a silicon substrate. This particular example embodiment shows a silicon wiring substrate.

The multi-chip package 700 may further include at least one semiconductor chip attached to the third chip 640. The semiconductor chip may be electrically connected to the substrate 610 directly or using the interposer substrate 680.

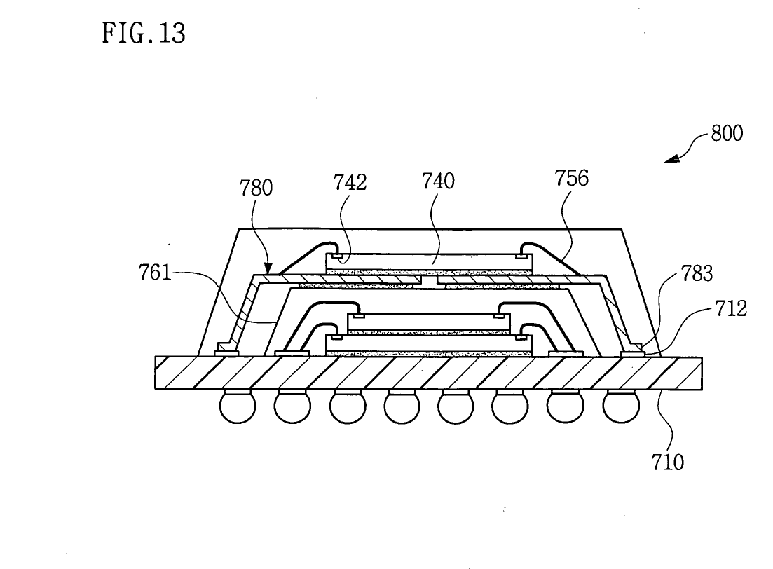

Referring to FIG. 13, a multi-chip package 800 may further comprise an interposer substrate 780 having patterns 783. The patterns 783 may extend beyond the first package body 761. The interposer substrate 780 may include a lead frame or a tape wiring substrate. This particular example embodiment shows a lead frame.

A third chip 740 may be attached to the interposer substrate 780. The third chip 740 may have third chip pads 742 formed on the active surface. Third bonding wires 756 may electrically connect the patterns 783 to the third chip pads 742.

Ends of the patterns 783 may be directly connected to substrate pads 712.

In accordance with the example embodiments of the present invention, a multi-chip package may include a substrate, a first chip group and a second chip group. The first chip group may be mounted on the substrate, e.g., stacked vertically, arranged horizontally, or a combination thereof relative to the substrate. The first chip group may be sealed to form a first package body. The first chip group may be tested at package level. The second chip group may be mounted on the first package body, e.g., stacked vertically, arranged horizontally, or a combination thereof relative to the first package body. The first package body and the second chip group may be sealed to form a second package body. Further package-level testing may be conducted against the first and second chip groups. The first chip group may have reliability lower than the second chip group. Thus, before mounting the second chip group, the first chip group may be package-level tested to avoid use of any faulty first chip group with a viable second chip group member. Therefore, a loss of a viable second chip group, e.g., caused by a faulty first chip group, may be reduced or eliminated. Improved overall production rates of multi-chip packages thereby results.

Further, the first chip group and second chip group may be passed through separate molding processes. The first chip group and second chip group may also be passed through separate test processes, e.g., each test conforming and appropriate to the characteristics of the chip group tested.

Although example, non-limiting embodiments of the present invention have been described in detail hereinabove, it should be understood that many variations and/or modifications of the basic inventive concepts herein taught, which may appear to those skilled in the art, will still fall within the spirit and scope of the example embodiments of the present invention as defined in the appended claims.

What is claimed is:

1. A multi-chip package comprising:
a substrate having substrate pads formed on a first surface and ball pads formed on a second surface, the first surface opposite the second surface, the ball pads being electrically connected to the substrate pads;
a first chip group including at least one semiconductor chip, the first chip group being mounted on the substrate and electrically connected to the substrate pads;
a first package body containing the first chip group;
a second chip group including at least one semiconductor chip, the second chip group being mounted on the first package body and electrically connected to the substrate pads; and
a second package body containing the first package body and the second chip group.

2. The multi-chip package of claim 1, wherein the first chip group includes two or more semiconductor chips, and at least two of the semiconductor chips are vertically arranged on the substrate.

3. The multi-chip package of claim 1, wherein the first chip group includes two or more semiconductor chips, and at least two of the semiconductor chips of the first group are horizontally arranged on the substrate.

4. The multi-chip package of claim 1, wherein the second chip group includes two ore more semiconductor chips, and at least two the semiconductor chips of the second group are vertically arranged on the first package body.

5. The multi-chip package of claim 1, wherein the second chip group includes two or more semiconductor chips, and at least two of the semiconductor chips of the second group are horizontally arranged on the first package body.

6. The multi-chip package of claim 1, further comprising an interposer substrate provided between the first package body and a semiconductor chip of the second chip group.

7. The multi-chip package of claim 6, wherein the interposer substrate is selected from a group consisting of a lead frame, a printed circuit board, a tape wiring substrate and a silicon substrate.

8. The multi-chip package of claim 7, wherein the semiconductor chips of the second chip group are wire bonded to the interposer substrate and the interposer substrate is wire bonded to the substrate pads.

9. The multi-chip package of claim 7, wherein the lowest semiconductor chip of the second chip group is flip chip bonded to the interposer substrate, and the interposer substrate is wire bonded to the substrate pads.

10. The multi-chip package of claim 7, wherein the interposer substrate has patterns extending beyond the first package body and connected to the substrate pads.

11. The multi-chip package of claim 1, wherein the first chip group includes memory chips.

12. The multi-chip package of claim 1, wherein the second chip group includes logic chips.

13. The multi-chip package of claim 1, further comprising solder balls formed on the ball pads of the substrate.

14. A method for manufacturing a multi-chip package comprising:
preparing a substrate, the substrate having substrate pads formed on a first surface and ball pads formed on a second surface, the first surface opposite the second surface, the ball pads being electrically connected to the substrate pads;
mounting a first chip group, including at least one semiconductor chip, on the substrate to electrically connect the first chip group to the substrate pads;
forming a first package body including the first chip group;
connecting test terminals to the ball pads and testing the first chip group;
mounting a second chip group, including at least one semiconductor chip, relative to the first package body to electrically connect the second chip group to the substrate pads; and
forming a second package body including the first package body and the second chip group.

15. The method of claim 14, wherein mounting the second chip group further comprises attaching an interposer substrate to the first package body to electrically connect the second chip group to the substrate, and the second chip group being mounted on the interposer substrate.

16. The method of claim 14, further comprising forming solder balls on the ball pads of the substrate.

17. A method for manufacturing a multi-chip semiconductor package, the method comprising:
packaging as a first package a first chip group including at least one semiconductor chip;
testing the first chip group at external terminals of the first package; and
packaging as a second package the first package and a second chip group including at least one semiconductor chip.

18. The method of claim 18 wherein the first chip group comprises at least one memory chip and the second chip group comprises at least one logic chip.

19. The method of claim 18 wherein an expected failure rate of the first chip group is greater than an expected failure rate of the second chip group.

20. The method of claim 18 further comprising discarding the first package upon failure in the testing thereof.
